(19) United States
(12) Patent Application Publication
(10) Pub. No.: US 2026/0358752 A1
(43) Pub. Date: Nov. 12, 2026

(54) IMAGE FORMING APPARATUS AND APPARATUS

(71) Applicant: CANON KABUSHIKI KAISHA, Tokyo (JP)

(72) Inventor: KOICHI MATSUMURA, Kanagawa (JP)

(21) Appl. No.: 19/666,803

(22) Filed: May 4, 2026

(30) Foreign Application Priority Data
May 9, 2025 (JP) 2025-078810

(51) Int. Cl. G03G 21/20; G03G 15/00; H05K 7/20

(52) U.S. Cl. CPC G03G 21/20; G03G 15/50; H05K 7/20909; H05K 7/20945; G03G 2215/00084; G03G 2215/00126

(57) ABSTRACT

An image forming apparatus includes a power supply unit configured to supply power to a load configured to be used in or related to image formation, a cooling fan configured to cool the power supply unit, and a processor configured to control driving of the cooling fan, wherein the image forming apparatus is configured to operate in a plurality of operation modes, and wherein the processor is configured to control the driving of the cooling fan based on an execution period in which the image forming apparatus is operating in a first operation mode among the plurality of operation modes, and a first setting value among a plurality of setting values each corresponding to a respective one of the plurality of setting values, the first setting value corresponding to the first operation mode.

### BACKGROUND

### Field of the Technology

The present disclosure relates to temperature control of an apparatus such as an image forming apparatus.

### Description of the Related Art

Image forming apparatuses, such as printers and multifunction apparatuses, include an AC-DC power supply configured to convert AC voltage into DC voltage for supplying power to respective loads. As the loads are driven, a current flowing through the AC-DC power supply increases, thereby causing components of the AC-DC power supply to generate heat. Accordingly, a cooling fan is provided in the vicinity of the AC-DC power supply to cool the components thereof.

However, by driving the cooling fan, power consumption increases. Further, the noise generated by the cooling fan also increases. Therefore, it is desirable to minimize the driving of the cooling fan. Japanese Patent Application Laid-open No. 2011-67973 discloses a technique for controlling the operation of a cooling fan based on whether the number of printed pages has reached or exceeded a predetermined number after starting a print job.

In Japanese Patent Application Laid-open No. 2011-67973, for a single print job, an optimal control of the cooling fan can be performed, thus, effective cooling of the AC-DC power supply is achieved. However, when multiple jobs are performed consecutively, optimal control of the cooling fan may not be achieved. For example, in a case where the AC-DC power supply has already been heated to some extent during a previous job and a subsequent job is started, the temperature of the AC-DC power supply may reach a level requiring cooling before the predetermined number of printed pages is reached.

The image forming apparatus is capable of performing various operations such as copying, scanning a document, and printing. Further, when these operations are not performed, the image forming apparatus stands by in a standby state or a sleep state. In order to operate in each of these operating states, two or more operation modes can be set for the image forming apparatus. The operation modes include a copy mode, a scan mode, a print mode, a standby mode, a sleep mode, etc. The power consumption of the image forming apparatus differs in each operation mode. Accordingly, depending on the order of the operation modes, the AC-DC power supply may not be cooled or, conversely, excessively cooled. Therefore, the technology of controlling the temperature of the AC-DC power supply appropriately according to the operation mode is required.

### SUMMARY

An image forming apparatus according to one embodiment of the present disclosure includes a power supply unit configured to supply power to a load configured to be used in or related to image formation, a cooling fan configured to cool the power supply unit, and a processor configured to control driving of the cooling fan, wherein the image forming apparatus is configured to operate in a plurality of operation modes, and wherein the processor is configured to control the driving of the cooling fan based on an execution period in which the image forming apparatus is operating in a first operation mode among the plurality of operation modes, and a first setting value among a plurality of setting values each corresponding to a respective one of the plurality of setting values, the first setting value corresponding to the first operation mode.

An apparatus according to another embodiment of the present disclosure includes a power supply unit configured to supply power to a load, a cooling fan configured to cool the power supply unit, and a processor configured to control driving of the cooling fan, wherein the apparatus is configured to operate in a plurality of operation modes, wherein the processor is configured to control the driving of the cooling fan based on an execution period in which the apparatus is operating in one mode among the plurality of operation modes, and a setting value corresponding to the one operation mode among a plurality of setting values each corresponding to a respective one of the plurality of setting values.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram of an image forming apparatus.

FIG. 2 is a schematic diagram of an image reading unit.

FIG. 3 is a circuit diagram of a power supply unit and a cooling fan.

FIG. 4 is a schematic diagram illustrating a control system.

FIGS. 5A, 5B, and 5C are schematic views illustrating temperature variations of a power supply unit.

FIG. 6 is a flow chart representing drive control of a cooling fan.

FIG. 7 is a flow chart representing the drive control of a cooling fan.

FIG. 8 is a schematic diagram illustrating temperature and a predicted value.

FIG. 9 is a schematic diagram illustrating temperature and a predicted value in a case where a drive control of a cooling fan is performed.

FIG. 10 is a schematic diagram illustrating temperature and a predicted value in a case where drive control of a cooling fan is not performed.

FIG. 11 is a schematic diagram illustrating a control system in a second embodiment.

FIG. 12 is a schematic diagram illustrating a control system in a third embodiment.

FIG. 13 is a schematic diagram illustrating an actual temperature waveform and a predicted value in a fourth embodiment.

### DESCRIPTION OF THE EMBODIMENTS

Now, a description is given of at least one embodiment of the present disclosure with reference to the accompanying drawings.

### First Embodiment

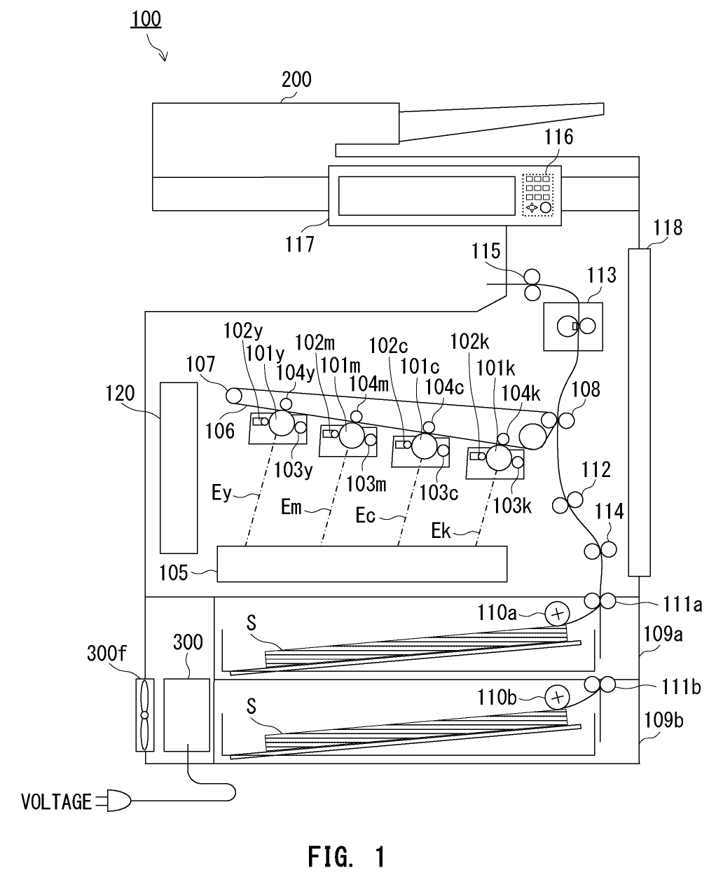

FIG. 1 is a schematic diagram of an image forming apparatus according to the first embodiment. The image forming apparatus 100 includes four image forming units, each corresponding to respective one of four colors, i.e., yellow, magenta, cyan, and black. Each image forming unit only differs in the color of the image to be formed, and performs the same operation with the same configuration. In FIG. 1, alphabets y, m, c, and d at the ends of reference numerals respectively represent colors of yellow, magenta, cyan, and black. In the following description, in a case where the members corresponding to the four colors are not distinguished, the suffixes y, m, c, and k of the reference numerals are omitted.

The image forming unit includes a photosensitive drum 101, a developer unit 102, a charging roller 103, and a primary transfer roller 104. The image forming apparatus 100 has, in addition to the image forming units, an exposure unit 105, an intermediate transfer belt 106, an intermediate transfer belt driving roller 107 (hereinafter, “driving roller 107”), a secondary transfer roller pair 108, and a fixing unit 113. For feeding a recording material S, the image forming apparatus 100 includes feeding cassettes 109a and 109b, pickup rollers 110a and 110b, feeding roller pairs 111a and 111b, a registration roller pair 112, a conveyance roller pair 114, and a discharge roller 115.

The image forming apparatus 100 includes an operation panel 117 and an image reading unit 200. The operation panel 117 is a user interface having an input interface and an output interface. The input interface includes various key buttons 116, a touch panel, etc. The output interface includes a display, a speaker, etc. The various key buttons 116A include a number button, a direction button, an operation start button, etc. The image reading unit 200 is a scanner for scanning a document.

The image forming apparatus 100 includes a cover 118 configured to be opened and closed, an apparatus control unit 120, a power supply unit 300, and a cooling fan 300f. The cover 118 is used in order to expose a conveyance path of the recording material S outside. The apparatus control unit 120 controls the overall operation of the image forming apparatus 100. The power supply unit 300 supplies power to each unit included in the image forming apparatus 100. The cooling fan 300f cools the power supply unit 300 by ventilating the power supply unit 300 or drawing in and discharging heat from the power supply unit 300.

In the image forming apparatus 100, the apparatus control unit 120 controls image forming operations according to print instructions via a network and copy instructions from the operation panel 117, for example. At first, the apparatus control unit 120 drives the photosensitive drum 101, the developer unit 102, the charging roller 103, the driving roller 107, and the fixing unit 113 using respective motors (not shown). At this time, the primary transfer roller 104 is driven to rotate by the rotation of the photosensitive drum 101. The intermediate transfer belt 106 is rotated by the driving roller 107. The secondary transfer roller pair 108 is driven to rotate by the intermediate transfer belt 106.

The photosensitive drum 101 is a drum-shaped photosensitive member having a photosensitive layer on its surface, and rotates about its drum axis. In a case where a high voltage is applied to the charging roller 103, the surface of the photosensitive drum 101 in contact with the charging roller 103 is charged to a uniform potential. The exposure unit 105 irradiates laser light modulated in accordance with image data onto the surface of the charged photosensitive drum 101. As a result, an electrostatic latent image corresponding to the image data is formed on the surface of the photosensitive drum 101.

The developer unit 102 develops the electrostatic latent image using toner to form a toner image on the surface of the photosensitive drum 101. The photosensitive drum 101 rotates to convey the formed toner image toward the primary transfer roller 104. During development, a high voltage is also applied to the developer unit 102 and the movement of the toner is controlled by the potential difference between the developer unit 102 and the photosensitive drum 101.

Thus, a yellow toner image is formed on the photosensitive drum 101y. A magenta toner image is formed on the photosensitive drum 101m. A cyan toner image is formed on the photosensitive drum 101c. A black toner image is formed on the photosensitive drum 101k.

The toner images of respective colors formed on the four photosensitive drums 101 are superimposed and transferred onto the rotating intermediate transfer belt 106 by the primary transfer rollers 104. At this time, a high voltage is applied to the primary transfer roller 104 to generate the electrostatic force necessary for transfer. The intermediate transfer belt 106 rotates to convey the transferred toner images to a position of the secondary transfer roller pair 108.

The recording material S is stored in feeding cassettes 109a and 109b and is fed in accordance with the timing of image formation by the image forming unit. The recording material S is fed at a predetermined timing by pickup rollers 110a and 110b from one of the feeding cassette 109a and the feeding cassette 109b designated by the apparatus control unit 120. The feeding roller pair 111a, 111b conveys the fed recording material S, one sheet at a time, to the registration roller pair 112 via the conveyance roller pair 114. The registration roller pair 112 waits for the recording material S with rotation stopped. The registration roller pair 112 corrects a skew in the recording material S.

The registration roller pair 112 conveys the recording material S to the secondary transfer roller pair 108 in synchronization with the timing at which the toner image carried on the intermediate transfer belt 106 is conveyed to the secondary transfer roller pair 108. As a result, the secondary transfer roller pair 108 can transfer toner images of respective colors to predetermined positions onto the recording material S in a single operation. At this time, a high voltage is applied to one of the secondary transfer roller pair 108. The recording material S onto which the toner image has been transferred is conveyed to the fixing unit 113.

The fixing unit 113 fixes the toner image to the recording material S by applying pressure and heat to the recording material S onto which the toner image has been transferred. The recording material S onto which the toner image has been transferred is discharged outside the image forming apparatus 100 by the discharge roller 115. Thus, a printed material, which is the recording material S with an image printed on, is obtained. In a case where an abnormality such as a jam occurs during conveyance of the recording material S and the recording material S remains in the conveyance path, a user can remove the remaining recording material S by opening the cover 118.

The image forming operations performed by the image forming apparatus 100 described above are carried out by operating the apparatus control unit 120, motors, sensors, a high-voltage power supply, and other components. The power supply unit 300 generates DC voltage to be supplied to the various components performing image formation in the image forming apparatus 100 from AC voltage supplied by a commercial power source to supply power to each component. The power supply unit 300 is cooled by the cooling fan 300f.

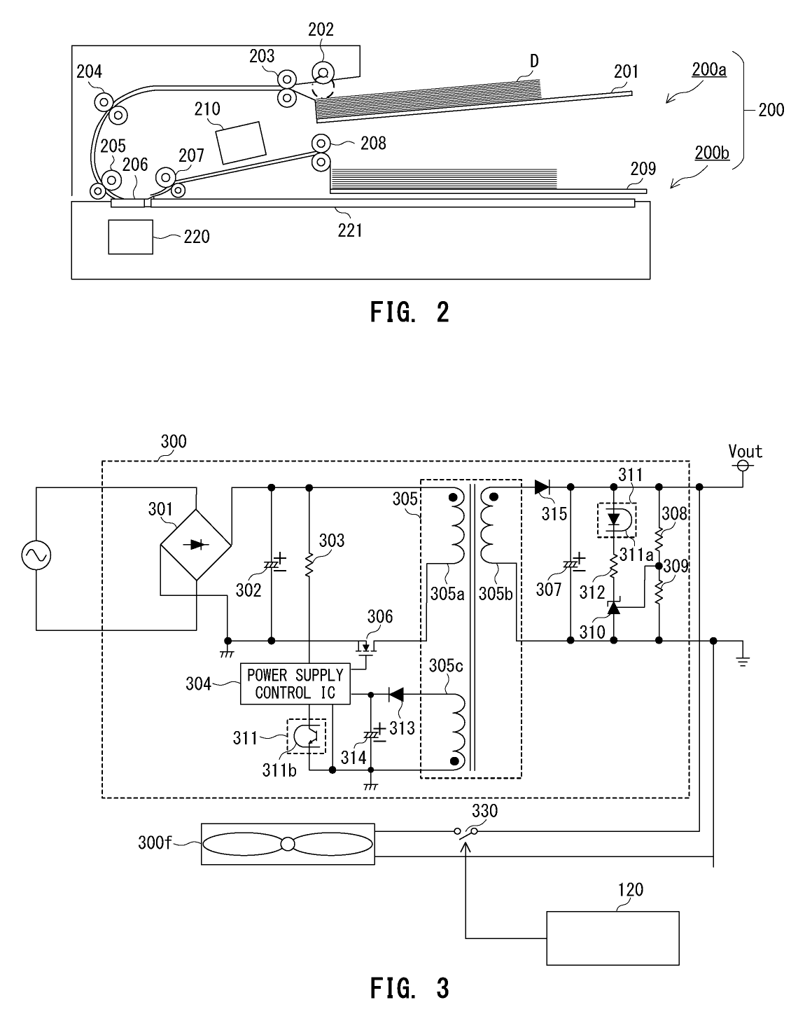

FIG. 2 is a schematic diagram of the image reading unit 200. As described above, the image reading unit 200 is provided in the image forming apparatus 100 and scans the image of a document D to generate image data. The image forming apparatus 100 prints an image based on the image data generated by the image reading unit 200 onto the recording material S, for example, during a copy job. The image reading unit 200 includes an auto document feeder (ADF) 200a and a platen reading unit 200b.

The ADF 200a includes a document tray 201 on which one or more documents D are stacked, an output tray 209 to which documents D are discharged, a conveyance mechanism that conveys documents D from the document tray 201 to the output tray 209, and a second reading unit 210 that reads the image on the back surface of the conveyed documents D. The conveyance mechanism includes a pickup roller 202, a separation drive roller pair 203, a conveyance roller pair 204, a read roller pair 205, and discharge roller pairs 207 and 208.

The platen reading unit 200b includes a first reading unit 220 for reading the image of the document D, a flow reading glass plate 206, and a platen 221. The first reading unit 220 is configured to be movable in a sub-scanning direction, which is the left-right direction in FIG. 2, by means of wires and a drive motor (not shown). The first reading unit 220 is used to read a front surface of the document D conveyed by the ADF 200a and the document D placed on the platen 221. The second reading unit 210 is used for reading the back surface of the document D conveyed by the ADF 200a. The image reading unit 200 reads an image from the document D in a flow reading mode in which an image on the front surface of the document D is read while conveying the document D stacked on the document tray 201, and in a fixed document reading mode in which an image on a glass-side surface of the document D placed on the platen 221 is read.

In a case where the flow reading mode is executed, the document D is fed by the pickup roller 202 and separated into individual sheets by the separation drive roller pair 203. The separated documents D are conveyed via the conveyance roller pair 204 by the read roller pair 205 toward the flow reading glass plate 206. The image on the front surface of the document D is read by the first reading unit 220 via the flow reading glass plate 206.

The first reading unit 220 and the second reading unit 210 irradiate light onto the document D during conveyance. The first reading unit 220 and the second reading unit 210 include photoelectric conversion elements, which receive the light reflected from the document D. The photoelectric conversion elements generate image data representing the image of the document D in response to the received reflected light. The image data is transmitted to the apparatus control unit 120.

When executing the fixed document reading mode, the document D is placed on the platen 221, and the first reading unit 220 moves in the sub-scan direction along the platen 221. As in the flow reading mode, the first reading unit 220 irradiates the document D with light, receives the reflected light to generate image data, and transmits the image data to the apparatus control unit 120.

### Power Supply Unit and Cooling Fan

FIG. 3 is a circuit diagram of the power supply unit 300 and the cooling fan 300f. The power supply unit 300 of the present embodiment is an AC-DC power supply that converts AC voltage supplied by the commercial power source into DC voltage and outputs it. The power supply unit 300 includes a primary circuit to which the commercial power source is connected, and a secondary circuit insulated from the primary circuit.

The power supply unit 300 includes an AC-DC conversion unit that converts AC voltage to DC voltage. The AC-DC conversion unit includes a bridge diode 301 and a capacitor 302. The bridge diode 301 serves as a rectifier circuit (rectifier or rectifying element) that rectifies the AC voltage. The capacitor 302 is an electrolytic capacitor or the like and serves as a smoothing circuit (smoothing element) that smooths the output current (pulsating current) of the bridge diode 301. As the pulsating current rectified by the bridge diode 301 flows into the capacitor 302, the capacitor 302 is charged and the current is smoothed into a DC voltage.

The DC voltage generated by the AC-DC conversion unit is supplied as the power supply voltage to a power supply control integrated circuit (IC) 304 via a startup resistor 303. In a case where DC voltage is supplied to the power supply control IC 304, the power supply unit 300 starts operation. The power supply control IC 304 is a control circuit for controlling an output voltage Vout to a target voltage. The AC-DC conversion unit is always operating as long as the plug of the image forming apparatus 100 is inserted into an outlet.

One end of the capacitor 302 is connected to one end of a primary winding 305a of a transformer 305. The other end of the capacitor 302 is connected to a source of a switching element 306. A drain of the switching element 306 is connected to the other end of the primary winding 305a. A gate of the switching element 306 is connected to the power supply control IC 304.

The power supply control IC 304, which is activated in a case where a predetermined voltage is charged into the capacitor 302, starts outputting a switching signal to the gate of the switching element 306. Through the switching of the switching element 306, the charge stored in the capacitor 302 is supplied to the primary winding 305a of the transformer 305 as an alternating current. The alternating current induces an alternating voltage in a secondary winding 305b, which corresponds to the turns ratio of the transformer 305.

A diode 315 and a capacitor 307 are arranged on the secondary side of the power supply unit 300. The diode 315 rectifies the AC voltage generated in the secondary winding 305b to produce a pulsating current. The capacitor 307 smooths the pulsating current generated by the diode 315 to produce a DC voltage. The voltage across the capacitor 307 becomes the output voltage Vout of the power supply unit 300.

Resistors 308 and 309, a shunt regulator 310, a photocoupler 311, and the current-limiting resistor 312 of the photocoupler 311 form a feedback circuit that feeds back the output voltage Vout to the power supply control IC 304. The photocoupler 311 is composed of a light-emitting diode 311a and a phototransistor 311b, and transmits a value corresponding to the output on the secondary side to the power supply control IC 304 while maintaining insulation between the primary and secondary sides of the power supply unit 300.

The resistors 308 and 309 form a voltage divider circuit that generates a detection voltage proportional to the output voltage Vout by dividing the output voltage Vout. The detected voltage is input to the shunt regulator 310. In a case where the detected voltage is higher than a reference voltage, the shunt regulator 310 increases the current flowing through the light-emitting diode 311a. In a case where the detected voltage is lower than the reference voltage, the shunt regulator 310 reduces the current flowing through the light-emitting diode 311a. When current flows through the light-emitting diode 311a, it emits light. The amount of light emitted by the light-emitting diode 311a varies in accordance with the current flowing through it. The phototransistor 311b receives light from light-emitting diode 311a. A current proportional to the light output from the light-emitting diode 311a flows through the phototransistor 311b. As a result, the output voltage Vout of the power supply unit 300 is fed back to the power supply control IC 304 via the photocoupler 311.

The power supply control IC 304 controls a duty cycle of the switching signal supplied to the switching element 306 based on the current flowing through the phototransistor 311b, so that the output voltage Vout matches the target voltage. The switching element 306 is, for example, a Metal-Oxide-Semiconductor Field-Effect Transistor (MOSFET). If the output voltage Vout is lower than the target voltage, more power must be supplied to the secondary side of the transformer 305. In this case, the power supply control IC 304 increases the time during which the switching element 306 is conductive, thereby current flowing through the primary winding 305a of the transformer 305 is increased. Conversely, in a case where the output voltage Vout is higher than the target voltage, it is necessary to reduce the power supplied to the secondary side of the transformer 305. In this case, the power supply control IC 304 reduces the time during which the switching element 306 is on, thereby decreasing the current flowing through the primary winding 305a of the transformer 305.

An auxiliary winding 305c is wound on a primary side of the same core as the primary winding 305a and the secondary winding 305b of the transformer. When the switching of the switching element 306 is started, a voltage is generated across the auxiliary winding 305c. This voltage causes current to flow through the diode 313 to charge the capacitor 314. In other words, a DC voltage is generated across the capacitor 314. The voltage across the capacitor 314 serves as a power source for the power supply control IC 304. When a sufficient DC voltage is supplied to the capacitor 314 via the auxiliary winding 305c of the transformer, the power supply control IC 304 cuts off the power that has been supplied via the startup resistor 303. As a result, current no longer flows through the startup resistor 303, thereby reducing power consumption.

The cooling fan 300f is connected to the output voltage Vout via a drive control switch 330 of the cooling fan 300f. The drive control switch 330 for the cooling fan 300f is controlled to be in a conductive state by a signal from the apparatus control unit 120 to thereby control the cooling fan 300f. The cooling fan 300f is driven by the output voltage Vout. Neither the power supply unit 300 nor the cooling fan 300f includes a temperature sensor for measuring temperature.

### Control Configuration of the Image Forming Apparatus

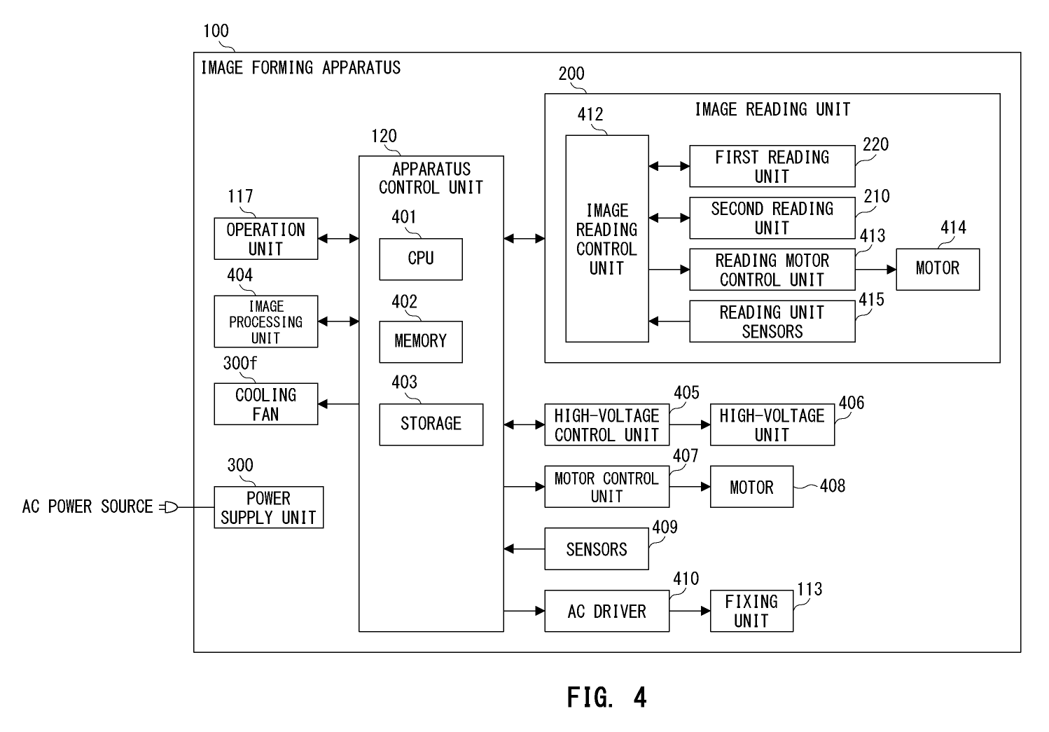

FIG. 4 is a schematic diagram illustrating the control system that controls the operation of the image forming apparatus 100. The power supply unit 300 provided in the image forming apparatus 100 is connected to an AC power source (commercial power source). Each component of the image forming apparatus 100 operates using power supplied from the power supply unit 300.

The apparatus control unit 120 includes a central processing unit (CPU) 401, a memory 402, and a storage 403. The apparatus control unit 120 is connected to an image processing unit 404, a high-voltage control unit 405, a motor control unit 407, sensors 409, an AC driver 410, the image reading unit 200, the operation panel 117, and the cooling fan 300f. The sensors 409 include a temperature sensor and a sheet detection sensor necessary for controlling the image forming apparatus 100. The apparatus control unit 120 is capable of transmitting and receiving data and signals with each of the connected components.

The CPU 401 executes various sequences related to a predetermined image forming sequence by executing various programs stored in the memory 402. The storage 403 is a storage device such as a hard disk drive (HDD) or a solid state drive (SSD). The storage 403 stores various data, such as setting values. The various data include, for example, setting values for the high-voltage unit 406 connected to the high-voltage control unit 405, commands for the motor control unit 407, information acquired from the operation panel 117, information transmitted to and received from the image reading unit 200, and setting values for controlling the cooling fan 300f.

The apparatus control unit 120 transmits to the image processing unit 404 the setting values of the various components installed inside the image forming apparatus 100 that are necessary for image processing by the image processing unit 404. The apparatus control unit 120 acquires signals from the sensors 409 and controls the high-voltage unit 406 via the high-voltage control unit 405 based on the acquired signals. The high-voltage control unit 405 drives the high-voltage unit 406 based on control signals acquired from the apparatus control unit 120. The high-voltage unit 406 includes, for example, the charging roller 103, the developer unit 102, and the primary transfer roller 104.

The motor control unit 407 drives a motor 408, which serves as the drive source for the load installed in the image forming apparatus 100, in response to commands received from the apparatus control unit 120. The apparatus control unit 120 transmits these commands to the motor control unit 407 based on signals from, for example, the sensors 409 and various sequences. The AC driver 410 controls a fixing heater (not shown) included in the fixing unit 113 so that its temperature reaches the level required for the fixing process. The fixing heater is a heater used for the fixing process.

The image reading unit 200 is controlled by an image reading control unit 412. The image reading control unit 412 includes a storage, a memory, and a CPU (not shown). The image reading control unit 412 is connected to a reading motor control unit 413, which controls motors 414 of the first reading unit 220, the ADF 200a, and the platen reading unit 200b. The image reading control unit 412 is also connected to reading unit sensors 415 and the like related to control within the image reading unit 200.

The first reading unit 220 and the second reading unit 210 are driven in response to a command from the image reading control unit 412. In response to a command from the image reading control unit 412 to enter either the flow reading mode or the fixed document reading mode, at least one of the motors 414 of the ADF 200a and the platen reading unit 200b is driven by the reading motor control unit 413.

The apparatus control unit 120 displays an operation screen on the display provided on the operation panel 117, allowing the user to set the type of the recording material S (sheet type) used for image formation and to set a reading mode. The apparatus control unit 120 acquires the information set by the user from the operation panel 117 and controls the operation sequence of the image forming apparatus 100 based on the information set by the user.

The apparatus control unit 120 transmits information indicating the status of the image forming apparatus 100 to the operation panel 117. The information indicating the status of the image forming apparatus 100 includes, for example, the number of images formed, the progress of the image forming operation, and information regarding sheet jams or double feeds during conveyance where multiple sheets are conveyed together. The operation panel 117 displays the information obtained from the apparatus control unit 120 on a display.

The apparatus control unit 120 stores thresholds and predicted values required to control the cooling fan 300f, which cools the power supply unit 300, in the storage 403. The CPU 401 controls the operation of the cooling fan 300f based on the usage status of various loads in the image forming apparatus 100, such as the high-voltage control unit 405, the high-voltage unit 406, the motor control unit 407, the motor 408, and the image reading unit 200. These loads are merely examples, and all components to which the power supply unit 300 supplies power are considered loads.

### Control of Cooling Fan

The control process for the cooling fan 300f will be described. In this embodiment, the cooling fan 300fis controlled according to the operation mode of the image forming apparatus 100. The operation modes include a copy mode, a scan mode, a print mode, a standby mode, a sleep mode, and others. The copy mode is an operation mode in which a copy job is performed to print an image of the document D, which is read by the image reading unit 200, onto the recording material S. The scan mode is an operation mode in which a scan job is performed to read an image of the document D using the image reading unit 200. The print mode is an operation mode that performs a print job in which an image is printed onto the recording material S based on the print job received from an external device such as a personal computer (PC). The standby mode is an operation mode in which an input of a job from the operation panel 117 or an external device is awaited. The sleep mode is an operation mode in which power consumption of the image forming apparatus 100 is reduced to a minimum necessary level. The sleep mode consumes less power than the standby mode. A temperature coefficient G is set for each operation mode. The temperature coefficient G is a set value determined in advance based on actual measurements taken prior to product shipment.

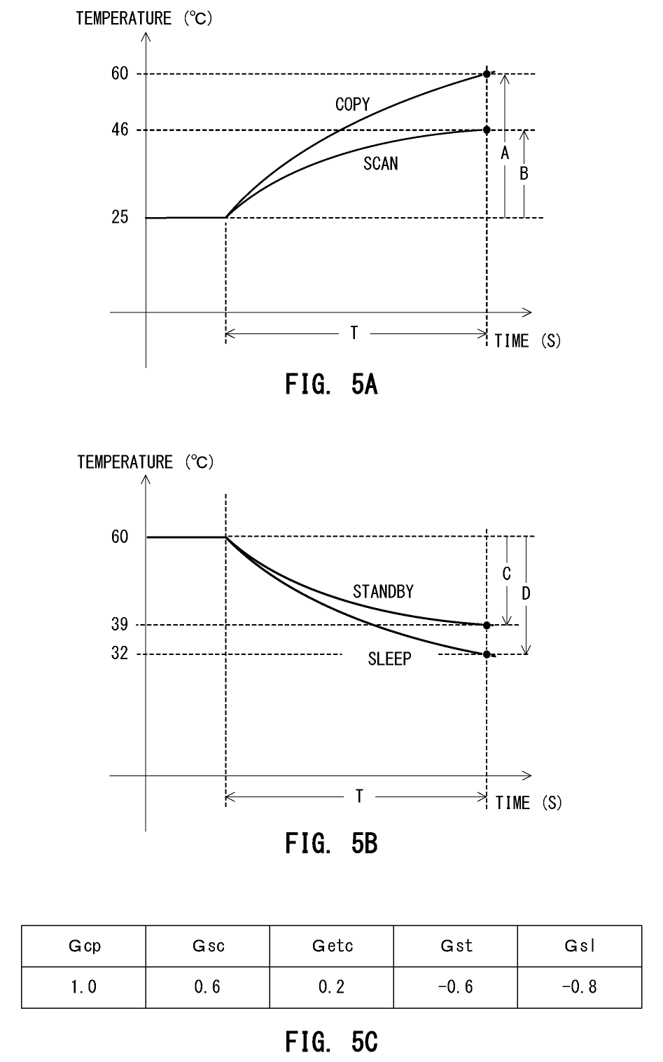

The temperature coefficient G is a value predetermined based on actual temperature measurements of components within the power supply unit 300 that require cooling by the cooling fan 300f (e.g., the transformer 305). FIGS. 5A, 5B, and 5C are schematic views illustrating temperature variations of the power supply unit 300 when it is operated in each operation mode. Here, the temperature variations of the transformer 305 are shown. Hereinafter, unless otherwise specified, references to temperature variations in the power supply unit 300 refer to the temperature variations in the transformer 305. FIG. 5A illustrates the temperature variations during the copy mode and the scan mode. FIG. 5B illustrates the temperature variations during the standby mode and the sleep mode. FIG. 5C illustrates the temperature coefficient G for each operation mode of the first embodiment.

In the scan mode, the image reading unit 200 mainly operates. In the copy mode, in addition to the image reading unit 200, loads such as the high-voltage unit 406, the motor 408, and the fixing unit heater 411 operate, resulting in higher power consumption than in the scan mode. Consequently, the temperature rise of the power supply unit 300 is greater in the copy mode than in the scan mode.

Here, let A° C. denote the temperature rise of the power supply unit 300 in a case where the image forming apparatus 100 operates in the copy mode for a fixed duration of T seconds while the power supply unit 300 is at 25° C. Further, let B° C. denote the temperature rise of the power supply unit 300 in a case where the image forming apparatus 100 operates in the scan mode for a fixed duration of T seconds while the power supply unit 300 is at 25° C. In FIG. 5A, A = 35° C. and B = 21° C. The temperature coefficient G for each operation mode in this embodiment is expressed as a value indicating how many times greater the temperature rise is for a specific operation mode. Taking the copy mode as a specific operation mode and setting the temperature coefficient Gcp for the copy mode to 1.0, the temperature coefficient Gsc for the scan mode becomes Gsc = Gcp × B/A = 0.6.

Although only the copy mode and the scan mode are described here, if differences in the temperature rise of the power supply unit 300 occur, temperature coefficients G may similarly be set for other operation modes, such as operation modes for a facsimile or a screen. Here, the temperature coefficient for other operation modes is set to G_(etc) = 0.2.

Similarly, temperature coefficients are set for operation modes such as the standby mode and the sleep mode, which are low-power consumption states. In FIG. 5B, in both the standby mode and the sleep mode, the temperature decreases over time due to low power consumption.

In the sleep mode, only the minimum necessary components, such as a part of the apparatus control unit 120 and some of the sensors 409, are active to enable recovery from a sleep state. In contrast, in the standby mode, in addition to the apparatus control unit 120, power is also supplied to the operation panel 117 and the image processing unit 404 so that printing can be started immediately. For this reason, the standby mode consumes more power than the sleep mode.

Here, assume that the power supply unit 300 transitions to the standby mode when its temperature is 60° C., and let C° C. be the amount of temperature drop that occurs over a fixed time T seconds. Further, assume that the power supply unit 300 transitions to the sleep mode when its temperature is 60° C., and let D° C. be the amount of temperature drop that occurs over the fixed time T seconds. In FIG. 5B, C = − 21° C. and D = 28°C. Since A = 35° C., C/A = − 0.6 and D/A = − 0.8. Therefore, the temperature coefficient Gst for the standby mode is Gcp × C/A = − 0.6, and the temperature coefficient Gsl for the sleep mode becomes Gcp × D/A = − 0.8.

Even for low-power consumption operation modes, the temperature coefficients G may be set not only for the standby mode and the sleep mode but also for other operation modes. Furthermore, while the standby mode and the sleep mode are defined here as having negative temperature coefficients (modes in which the temperature decreases), they may, for example, have positive temperature coefficients (modes in which the temperature increases) if the power consumption during standby is high.

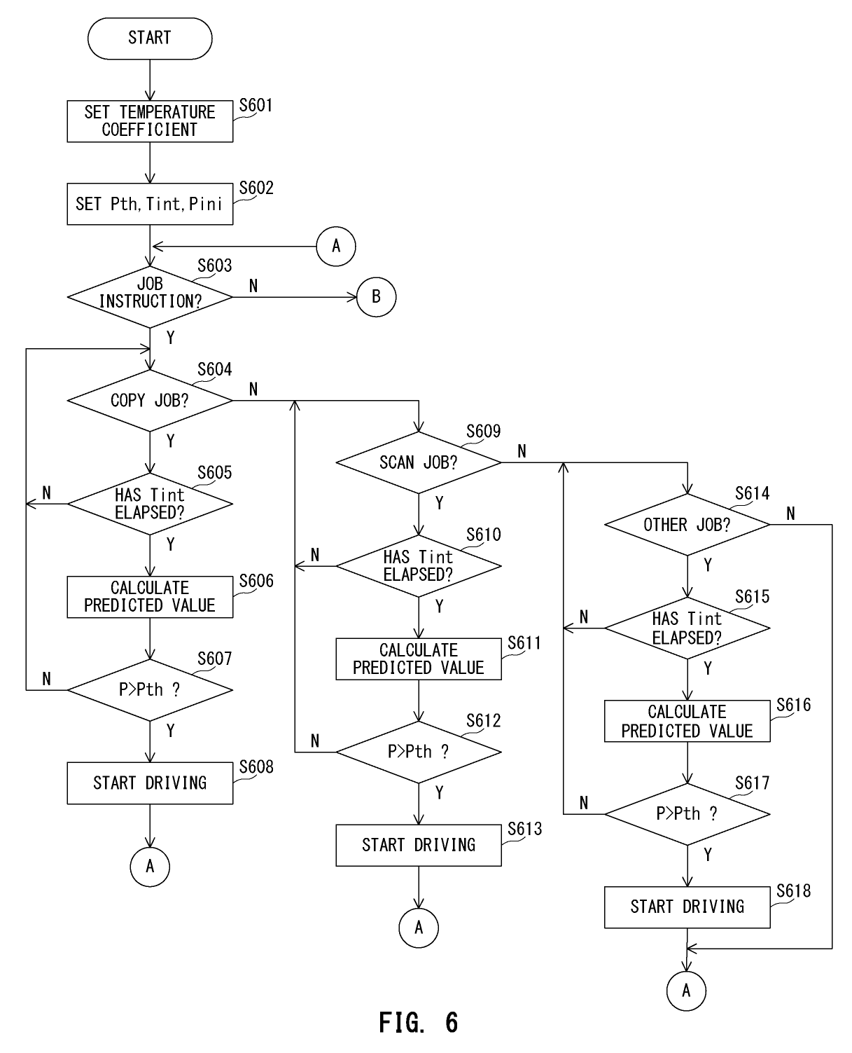

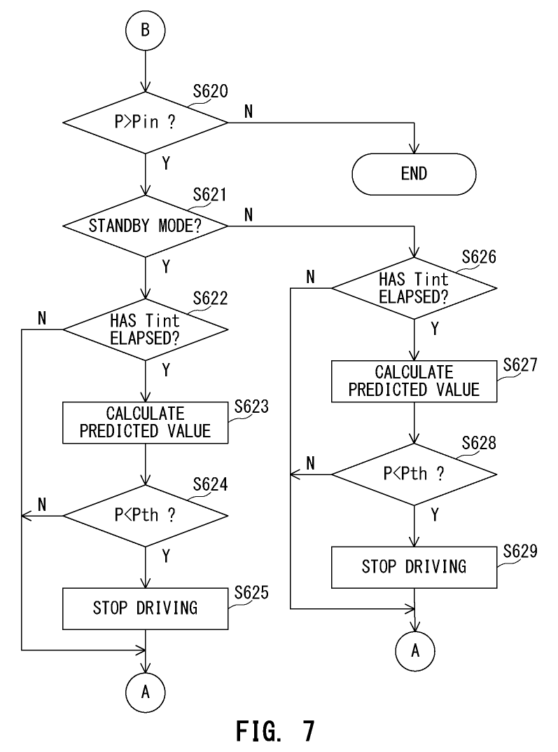

FIGS. 6 and 7 are flowcharts illustrating the drive control of the cooling fan 300f.

The apparatus control unit 120 sets the temperature coefficients G for each operation mode, which are stored in the storage 403, in the memory 402 (STEP S601). The apparatus control unit 120 sets a threshold Pth, an interval Tint, and an initial predicted value Pini, which are stored in the storage 403 and used to determine when to start driving the cooling fan 300f, in the memory 402 (STEP S602). The initial predicted value Pini is an initial value of the predicted value P described below. Further, the initial predicted value Pini is an initial value of the predicted value P when the power to the image forming apparatus 100 is turned on, and is stored in advance in the storage 403. After setting these values, the apparatus control unit 120 determines whether a job instruction is present (STEP S603).

If a job instruction is present and the job instructs the copy job (STEP S603: Y, STEP S604: Y), the apparatus control unit 120 sets the operation mode to the copy mode. The apparatus control unit 120 determines whether the copy job has been executed (continuously running) for an interval of Tint seconds (STEP S605). If the execution time of the copy job has not reached the interval Tint seconds (STEP S605: N), the apparatus control unit 120 returns to the processing of STEP S604 to determine whether the job instructs the copy job. When returning from the processing of STEP S605 to the processing of STEP S604 and STEP S605, the measurement of the interval Tint continues.

If the copy job has been executed for the interval Tint seconds (the copy job duration time has reached Tint) (STEP S605: Y), the apparatus control unit 120 adds the temperature coefficient Gcp (1.0) for the copy mode to the current predicted value P. Thus, a new predicted value P (STEP S606) is calculated. In a case where this processing is performed for the first time after the image forming apparatus 100 is powered on, since the current predicted value P is the initial predicted value Pini, the new predicted value P becomes (Pini + 1.0). In other words, in a case where the interval Tini elapses for the first time after the image forming apparatus 100 is powered on, the temperature coefficient G is added to the initial predicted value Pini. The predicted value P is a value determined by calculating the temperature coefficient for the operation mode and an execution period of the operation mode, and it corresponds to the temperature of the power supply unit 300 (transformer 305). Alternatively, the predicted value P immediately before turning off the power to the image forming apparatus 100 is stored in the storage 403. In this case, when the power to the image forming apparatus 100 is turned on, the predicted value P at the time of power-on is determined based on an elapsed time since power-off. The elapsed time can be calculated by utilizing a timer IC that manages time information.

The apparatus control unit 120 determines whether the predicted value P exceeds the threshold Pth (STEP S607). If the predicted value P does not exceed the threshold Pth (STEP S607: N), the apparatus control unit 120 returns to the processing of STEP S604 to determine whether the job instructs the copy job. Specifically, the predicted value P is determined by adding the temperature coefficient G according to the operation mode to the predicted value at that time for each predetermined length of execution time equivalent to an interval Tint. While the copy mode is being executed, the apparatus control unit 120 repeats the processing of STEP S604, STEP S605, and STEP S606 and continuously adds the temperature coefficient Gcp (1.0) for the copy mode every interval Tint seconds to determine whether the predicted value P has exceeded the threshold Pth.

If the predicted value P exceeds the threshold Pth (STEP S607: Y), the apparatus control unit 120 drives the cooling fan 300f (STEP S608). After driving the cooling fan 300f, the apparatus control unit 120 returns to the processing of STEP S603 to determine whether a job instruction is present. Note that when returning from the processing of STEP S607 to the processing of STEP S604 and STEP S605, a new measurement of the interval Tint is started.

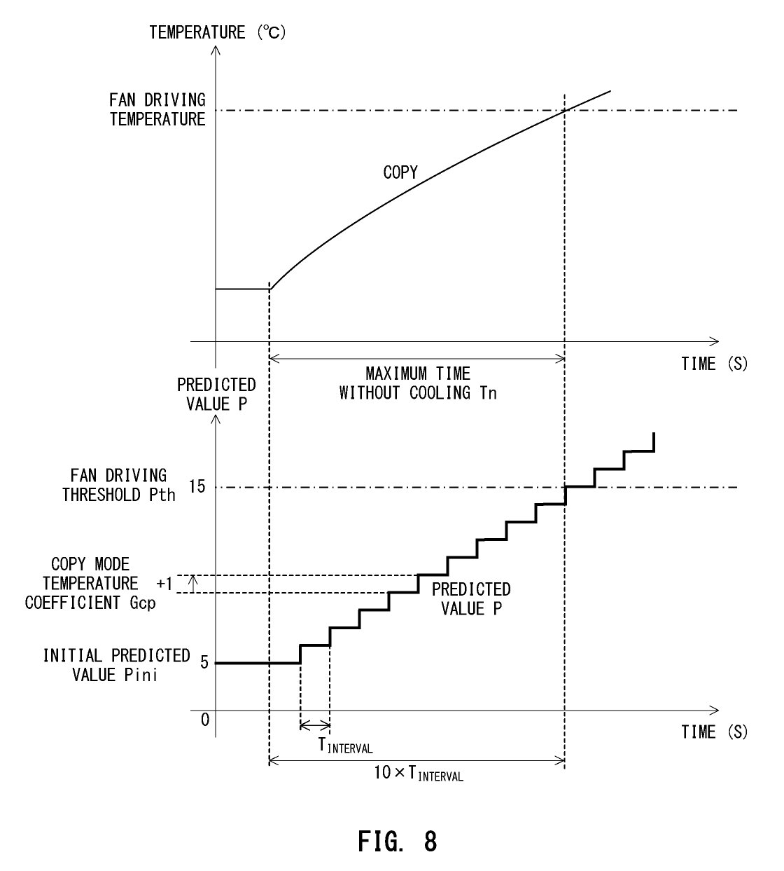

FIG. 8 is a schematic diagram illustrating temperature and the predicted value P based on the processing of STEP S604 to STEP S608. The upper graph in FIG. 8 represents the actual measured values of temperature rise during the copy mode. If the image forming apparatus 100 is operated in the copy mode without driving the cooling fan 300f, the power supply unit 300 will reach the limit temperature in a maximum time without cooling Tn (seconds). The lower graph in FIG. 8 illustrates a variation in the predicted value P. The predicted value P increases stepwise because the temperature coefficient for the copy mode Gcp = 1.0 is continuously added every interval Tint seconds. Here, if the maximum time without cooling is reached in 10 × Tint seconds, the threshold Pth is set to 10 × temperature coefficient Gcp + initial predicted value Pini. For example, if the initial predicted value Pini is 5, the threshold Pth is 15.

If the job does not instruct the copy job, or if the copy job has ended (STEP S603: Y, STEP S604: N), the apparatus control unit 120 determines whether the job instructs a scan job (STEP S609). If the scan job is instructed (STEP S609: Y), the apparatus control unit 120 sets the operation mode to the scan mode.

The apparatus control unit 120 determines whether the scan job has been executed for an interval Tint seconds (STEP S610). If the duration time of the scan job has not reached the interval Tint seconds (STEP S610: N), the apparatus control unit 120 returns to the processing of STEP S609 and determines whether the job instructs the scan job.

If the scan job has been executed for the interval Tint seconds (i. e., the scan job duration time has reached Tint) (STEP S610: Y), the apparatus control unit 120 adds the temperature coefficient Gsc (0.6) for the scan mode to the current predicted value P. Thus, a new predicted value P is calculated (STEP S611). In a case where this processing is performed for the first time, since the current predicted value P is the initial predicted value Pini, the new predicted value P becomes (Pini + 0.6).

The apparatus control unit 120 determines whether the predicted value P exceeds the threshold Pth (STEP S612). If the predicted value P does not exceed the threshold Pth (STEP S612: N), the apparatus control unit 120 returns to the processing of STEP S609 to determine whether the job instructs the scan job. While the scan mode is set, the apparatus control unit 120 repeats the processing of STEP S609, STEP S610, and STEP S611 and continuously adds the temperature coefficient Gsc (0.6) for the scan mode every interval Tint seconds to determine whether the predicted value P has exceeded the threshold Pth.

If the predicted value P exceeds the threshold Pth (STEP S612: Y), the apparatus control unit 120 drives the cooling fan 300f (STEP S613). After driving the cooling fan 300f, the apparatus control unit 120 returns to the processing of STEP S603 to determine whether a job instruction is present. With respect to the measurement of the interval Tint, it is the same as that of the case of the copy job.

If the job does not instruct the scan job, or if the scan job has ended (STEP S609: N), the apparatus control unit 120 determines whether the job instructs another job (STEP S614). If another job is not instructed (STEP S614: N), the apparatus control unit 120 returns to the processing of STEP S603, without driving the cooling fan 300f, and determines whether a job instruction is present. If another job is instructed (STEP S614: Y), the apparatus control unit 120 sets the operation mode to another operation mode.

The apparatus control unit 120 determines whether another job has been executed for an interval Tint seconds (STEP S615). If the duration time of the job has not reached the interval Tint seconds (STEP S615: N), the apparatus control unit 120 returns to the processing of STEP S614 and determines whether the job instructs another job.

If another job has been executed for the interval Tint seconds (STEP S615: Y), the apparatus control unit 120 adds a temperature coefficient Getc (0.2) for another mode to the current predicted value P. Thus, a new predicted value P is calculated (STEP S616). In a case where this processing is performed for the first time, since the current predicted value P is the initial predicted value Pini, the new predicted value P becomes (Pini + 0.2).

The apparatus control unit 120 determines whether the predicted value P exceeds the threshold Pth (STEP S617). If the predicted value P does not exceed the threshold Pth (STEP S617: N), the apparatus control unit 120 returns to the processing of STEP S614 to determine whether the job instructs another job. While another mode is set, the apparatus control unit 120 repeats the processing of STEP S614, STEP S615, and STEP S616 and continuously adds the temperature coefficient Getc (0.2) for another mode every interval Tint seconds to determine whether the predicted value P has exceeded the threshold Pth.

If the predicted value P exceeds the threshold Pth (STEP S617: Y), the apparatus control unit 120 drives the cooling fan 300f (STEP S618). After driving the cooling fan 300f, the apparatus control unit 120 returns to the processing of STEP S603 to determine whether a job instruction is present. With respect to the measurement of Interval Tint, it is the same as that of the case of the copy mode.

When there is no instruction for a job (STEP S603: N), the apparatus control unit 120 determines whether the predicted value P exceeds the initial predicted value Pini (STEP S620). For example, if the processing of STEP S604 to STEP S618 has been performed in advance, the predicted value P may exceed the initial predicted value Pini because the temperature coefficient G corresponding to the content of the job has been added.

If the predicted value P exceeds the initial predicted value Pini (STEP S620: Y), the operation mode of the apparatus control unit 120 is the standby mode or the sleep mode. The apparatus control unit 120 determines whether the operation mode is the standby mode (STEP S621).

If the operation mode is the standby mode (STEP S621: Y), the apparatus control unit 120 determines whether the standby mode remains set during the interval of Tint seconds set in the processing of STEP S602 (STEP S622). If the duration time of the standby mode reaches the interval Tint seconds (STEP S622: Y), the apparatus control unit 120 subtracts the temperature coefficient Gst (− 0.6) for the standby mode from the current predicted value P. Thus, a new predicted value P is calculated (STEP S623).

The apparatus control unit 120 determines whether the predicted value P is below the threshold Pth (STEP S624). The apparatus control unit 120 repeats the processing of STEP S603, STEP S620 to STEP S624 while the standby mode is set. Thus, the apparatus control unit 120 continues to subtract the temperature coefficient Gcp (− 0.6) for the standby mode every interval Tint seconds and determines whether the predicted value P has fallen below the threshold Pth.

If the predicted value P has not fallen below the threshold Pth (STEP S624: N), the apparatus control unit 120 returns to the processing of STEP S603 to determine whether a job instruction is present. If the predicted value P has fallen below the threshold Pth (STEP S624: Y), the apparatus control unit 120 stops the operation of the cooling fan 300f (STEP S625). After stopping the operation of the cooling fan 300f, the apparatus control unit 120 returns to the processing of STEP S603 and determines whether a job instruction is present. The measurement of the interval Tint is the same as in the copy mode.

If the operation mode is not the standby mode (STEP S621: N), the apparatus control unit 120 determines that the operation mode is the sleep mode. The apparatus control unit 120 determines whether the sleep mode has been executed for the interval Tint seconds (STEP S626). If the duration of the sleep mode reaches the interval Tint seconds (STEP S626: Y), the apparatus control unit 120 subtracts the temperature coefficient Gsl (− 0.8) for the sleep mode from the current predicted value P. Thus, a new predicted value P is calculated (STEP S627).

The apparatus control unit 120 determines whether the predicted value P is below the threshold Pth (STEP S628). The apparatus control unit 120 repeats the processing of STEP S603, STEP S620, STEP S621, STEP S626 to STEP S628 while the sleep mode is set. Thus, the apparatus control unit 120 continues to subtract the temperature coefficient Gsl (− 0.8) for the standby mode every interval Tint seconds and determines whether the predicted value P has fallen below the threshold Pth.

If the predicted value P has not fallen below the threshold Pth (STEP S628: N), the apparatus control unit 120 returns to the processing of STEP S603 to determine whether a job instruction is present. If the predicted value P has fallen below the threshold Pth (STEP S628: Y), the apparatus control unit 120 stops the operation of the cooling fan 300f (STEP S629). After stopping the operation of the cooling fan 300f, the apparatus control unit 120 returns to the processing of STEP S603 and determines whether a job instruction is present. With respect to measurement of Interval Tint, it is the same as that of the case of the copy mode.

If the predicted value P does not exceed the initial predicted value Pini (STEP S620: N), the apparatus control unit 120 ends the process. For example, even after the predicted value P has increased due to a print job, a copy job, a scan job, or the like, the predicted value P decreases due to the standby or the sleep, thus the predicted value P falls below an initial predicted value Pint. In this way, the apparatus control unit 120 can control driving of the cooling fan 300f based on the sum of the predicted values P for each operation mode to be executed.

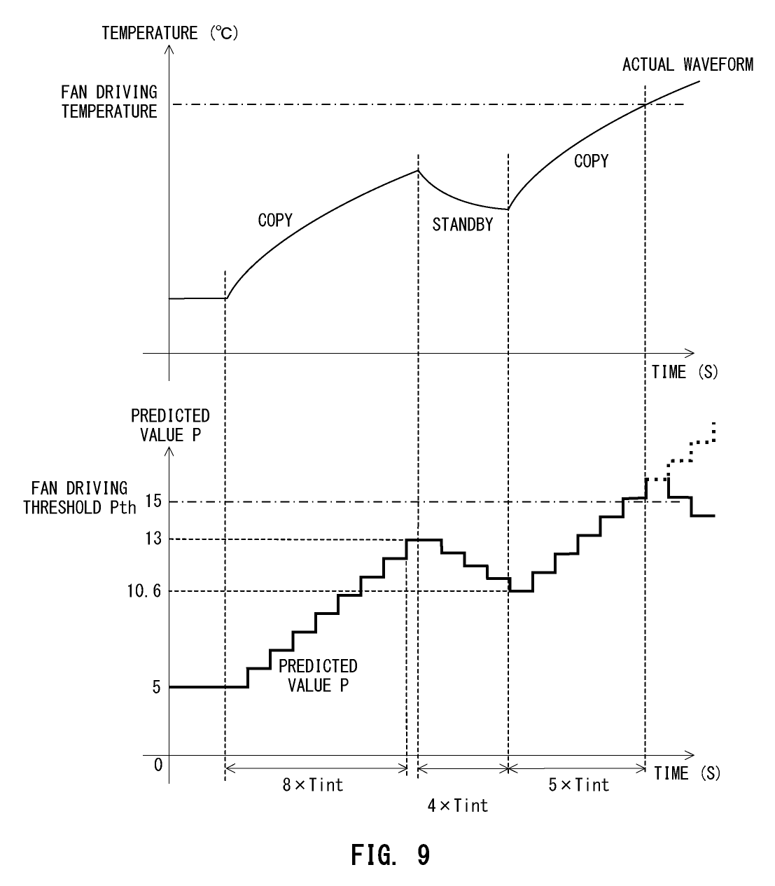

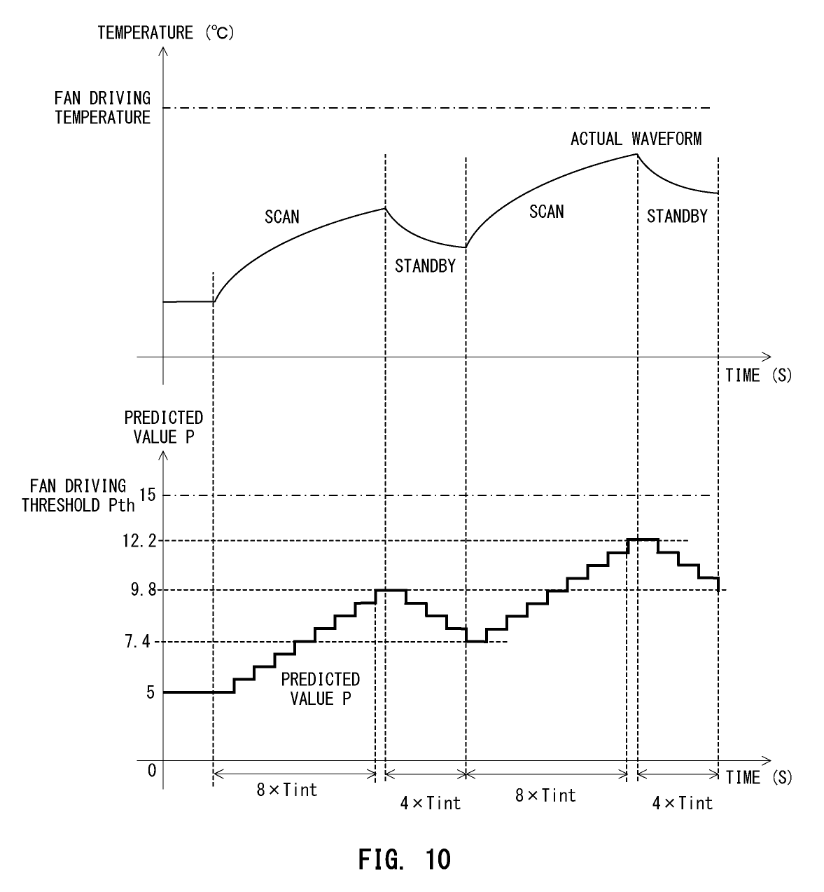

Several patterns are described regarding cases where the cooling fan 300f is operated and cases where it is not. FIG. 9 is a schematic diagram illustrating temperature and a predicted value P in a case where the cooling fan 300f is driven. FIG. 10 is a schematic diagram illustrating temperature and a predicted value P in a case where the cooling fan 300f is not driven. With respect to the temperature coefficient G for each operation mode described below, the temperature coefficient G illustrated in FIG. 5C is used.

FIG. 9 illustrates the temperature variations in the power supply unit 300 and the variations in the predicted value P in a case where the copy job is executed, the standby mode is performed after completion of the copy job, and then another copy job is executed. According to the upper graph in FIG. 9, during the execution of the copy job following the standby mode, the temperature of the power supply unit 300 reaches the temperature requiring cooling by the cooling fan 300f. According to the lower graph in FIG. 9, in a case where the copy job is executed with the initial predicted value Pini = 5 and 8×Tint seconds have elapsed, the predicted value P becomes P = Pini + 8×Gcp = 5 + 8×1 = 13. After the copy job, when 4×Tint seconds have elapsed in the standby mode, the predicted value P becomes P = 13 + 4×Gst = 13 + 4× (− 0.6) = 10.6. Subsequently, the copy job is executed again, and after 5×Tint seconds have elapsed, P becomes P = 10.6 + 5×Gcp = 10.6 + 5×1 = 15.6. Since the predicted value P exceeds the fan driving threshold Pth = 15, driving of the cooling fan 300f is started.

In a case where the cooling fan 300f is not driven, the predicted value P continues to rise (dashed line in the lower graph of FIG. 9). In the first embodiment, driving the cooling fan 300f causes the predicted value P to decrease. According to the lower graph in FIG. 9, after the predicted value P exceeds the fan driving threshold Pth, the predicted value P decreases due to the operation of the cooling fan 300f and falls below the fan driving threshold Pth (solid line). The cooling fan 300f is stopped after the predicted value P has decreased sufficiently below the fan driving threshold Pth. For this reason, the threshold for stopping the cooling fan 300f is set to a value sufficiently lower than the fan driving threshold Pth. This prevents frequent on/off cycling of the cooling fan 300f.

FIG. 10 illustrates the temperature variations in the power supply unit 300 and the variations in the predicted value P in a case where the scan job is executed, the standby mode is executed after completion of the scan job, then the scan job is executed again, and the standby mode is executed after completion of the scan job. According to the upper graph of FIG. 10, the temperature of the power supply unit 300 does not reach the temperature at which cooling is required. According to the lower graph in FIG. 10, in a case where the scan job is executed with the initial predicted value Pini = 5 and 8×Tint seconds have elapsed, the predicted value P becomes P = Pini + 8×Gsc = 5 + 8×0.6 = 9.8. After the scan job, when 4×Tint seconds have elapsed in the standby mode, the predicted value P becomes P = 9.8 + 4× (− 0.6) = 7.4. Thereafter, when the scan job is executed again, the temperature coefficient Gsc (0.6) is added every Tint seconds. Even after 8×Tint seconds have elapsed, as shown in FIG. 10, the predicted value P is P = 7.4 + 8×Gsc = 7.4 + 8×0.6 = 12.2, which does not exceed the threshold Pth. In this case, even if the scan mode ends, the cooling fan 300f will not be driven. After the scan job, when 4×Tint seconds have elapsed in the standby mode, the predicted value P becomes P = 12.2 + 4×Gst = 12.2 + 4 × (− 0.6) = 9.8.

However, in a case where the execution of the scan job and the transition to the standby mode are repeated, the predicted value P at the start of each scan job increases with each repetition. Consequently, during the scan job, the predicted value P may exceed the threshold Pth, causing the cooling fan 300f to be driven.

FIG. 9 illustrates the case where the standby mode occurs between the copy jobs, however, there are also a case where the standby mode is executed after executing the copy job, and then the print job or the scan job is executed. Even in this case, since the predicted value P is not reset and the temperature coefficient G is added or subtracted, the predicted value P calculated in the current operation mode reflects the results of the predicted value calculations from the previous operation modes. Thus, even in continuous operation modes, the predicted value P is added to or subtracted by the temperature coefficient G set for the current operation mode at predetermined time intervals (interval Tint).

### Second Embodiment

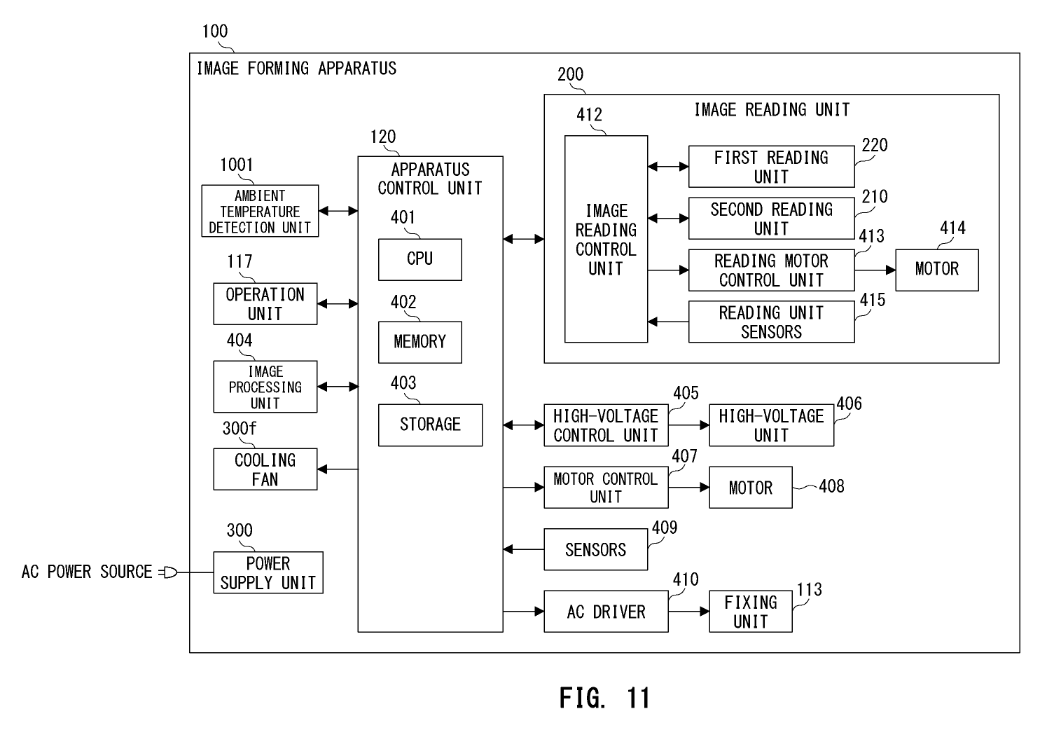

The image forming apparatus 100 of a second embodiment differs from the image forming apparatus 100 of the first embodiment in the configuration of the control mechanism. FIG. 11 is a schematic diagram illustrating the control system in the second embodiment.

The control system of the image forming apparatus 100 of the second embodiment includes an ambient temperature detection unit 1001 added to the configuration of the control system of the first embodiment (see FIG. 4). The ambient temperature detection unit 1001 detects the temperature around the image forming apparatus 100 and transmits the temperature data, which is a detection result, to the apparatus control unit 120.

A correction coefficient Ctmp is predetermined based on the temperature data obtained by the ambient temperature detection unit 1001. The correction coefficient Ctmp is a correction value for the temperature coefficient G. For example, the higher the temperature around the image forming apparatus 100, the larger the value of the correction coefficient Ctmp becomes.

The apparatus control unit 120 corrects the temperature coefficient G for each operation mode based on the correction coefficient Ctmp. The corrected temperature coefficient Gco-cp for the copy mode is calculated as Gco-cp = Gcp × Ctmp. The temperature coefficients for other operation modes are corrected in the same manner. The drive control of the cooling fan 300f is performed in the same manner as in the first embodiment.

### Third Embodiment

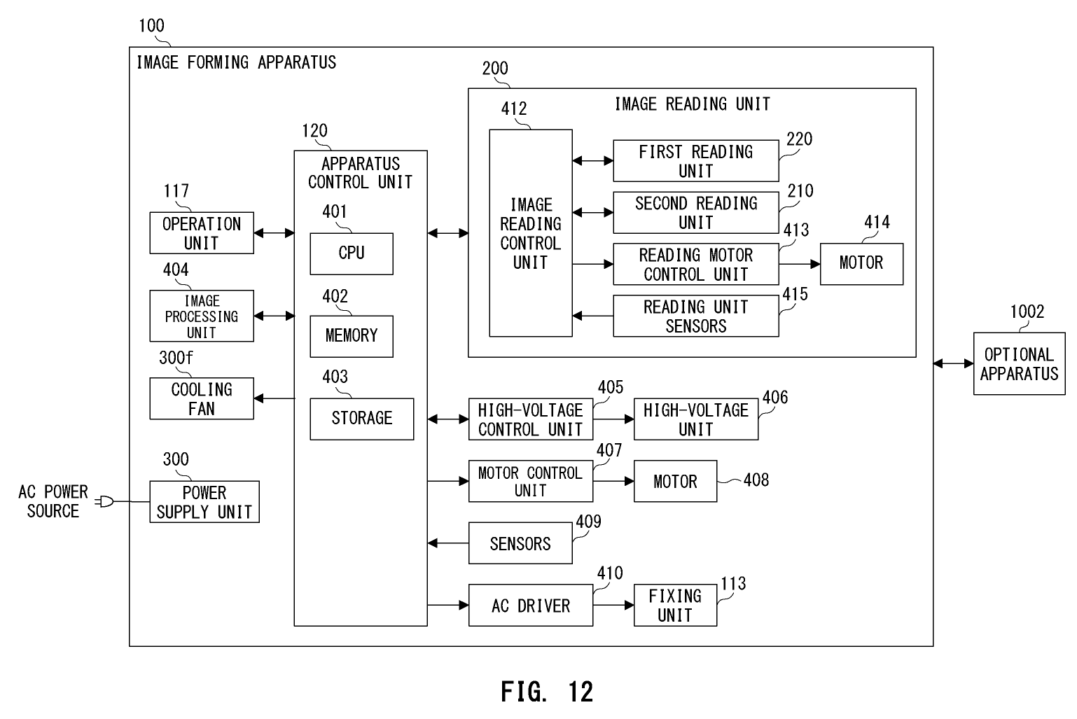

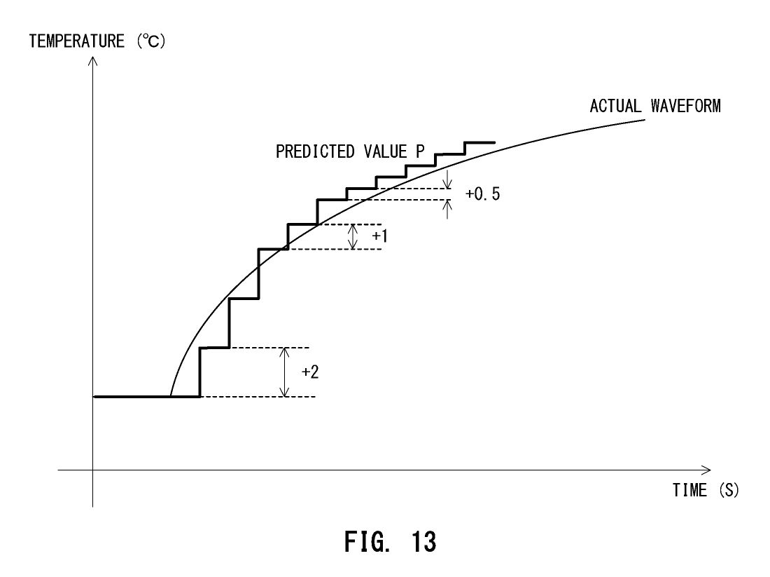

The image forming apparatus 100 of a third embodiment differs from the image forming apparatus 100 of the first embodiment in the configuration of the control mechanism. FIG. 12 is a schematic diagram illustrating the control system in the third embodiment.

The control system of the image forming apparatus 100 of the third embodiment includes an optional apparatus 1002 added to the configuration of the control system of the first embodiment (see FIG. 4). The optional apparatus 1002 is, for example, a finisher that performs post-processing such as stapling, folding, or binding of printed materials. The optional apparatus 1002 is not limited to the finisher, it may be any apparatus capable of being connected to the image forming apparatus 100. The optional apparatus 1002 is, for example, supplied with power from the power supply unit 300 when in use.

A correction coefficient Cext is predetermined based on the type of the optional apparatus 1002 to be connected. The correction coefficient Cext is a correction value for the temperature coefficient G. The value of the correction coefficient Cext changes depending on the type of the optional apparatus 1002. For example, the higher the power consumption of the optional apparatus 1002, the larger the value of the correction coefficient Cext becomes.

The apparatus control unit 120 corrects the temperature coefficient G for each operation mode based on the correction coefficient Cext. The corrected temperature coefficient Gco-cp for the copy mode is calculated as Gco-cp = Gcp × Cext. The temperature coefficients for other operation modes are corrected in the same manner. The drive control of the cooling fan 300f is performed in the same manner as in the first embodiment.

If the optional apparatus 1002 is connected but not in use, correction of the temperature coefficient G using the correction coefficient Cex is not required. For example, if the optional apparatus 1002 is a finisher, it is not used in the scan mode. Therefore, the temperature coefficient Gsc for the scan mode is not corrected by the correction coefficient Cex. Furthermore, even in the copy mode, if the destination for the recording material S is not the optional apparatus 1002, the optional apparatus 1002 is not used. Also, the temperature coefficient Gcp for the copy mode is not corrected by the correction coefficient Cext in this case.

The control system of the image forming apparatus 100 may be configured by combining the second and third embodiments. That is, the image forming apparatus 100 may be provided with both the ambient temperature detection unit 1001 and the optional apparatus 1002. In this case, the corrected temperature coefficient Gco-cp for the copy mode is calculated as Gco-cp = Gcp × Ctmp × Cext.

### Fourth Embodiment

The configuration of the image forming apparatus 100 in a fourth embodiment is the same as that of the first embodiment. FIG. 13 is a schematic diagram illustrating an actual temperature waveform and a predicted value P in a fourth embodiment.

In the first embodiment, an example in which the temperature coefficient G for each operation mode is set to a single constant is disclosed. However, the actual temperature tends to rise rapidly at the start of a job and then level off gradually over time, as shown in the actual waveform in FIG. 13. Therefore, in the fourth embodiment, the temperature coefficient G for each operation mode is changed according to the elapsed time to control the operation of the cooling fan 300f. For example, in FIG. 13, the temperature coefficient Gcp for the copy mode is set to2 during a period from 0 seconds to 3×Tint seconds, is set to 1 during a period from 4×Tint seconds to 5×Tint seconds, and is set to 0.5 from 6×Tint seconds onward. The drive control of the cooling fan 300f is executed in the same manner as in the first embodiment.

As described in the first through fourth embodiments, the predicted value is adjusted by addition or subtraction depending on the operation mode. For each operation mode, the temperature coefficient to be added to the predicted value and the temperature coefficient to be subtracted from the predicted value are set depending on a type of the operation mode. For example, in operation modes such as the copy mode, the scan mode, and the print mode that drive the load, the temperature coefficient that is to be added to the predicted value is set. In operation modes such as the standby mode and the sleep mode that do not drive the load, the temperature coefficient that is to be subtracted from the predicted value is set.

The predicted value is adjusted at predetermined time intervals (interval Tint) to ensure that the predicted value remains close to the actual measured temperature at all times. When the predicted value exceeds a threshold, the cooling fan 300f is driven, and when the predicted value falls below the threshold, driving of the cooling fan 300f is stopped. As a result, the cooling fan 300f is driven only for the necessary duration. The cooling fan 300f may be provided with hysteresis by setting a threshold for stopping driving of the cooling fan 300f lower than a threshold for starting driving thereof.

The temperature coefficient G set for each of the multiple operation modes may be corrected according to the ambient temperature or the connected optional apparatus (STEP Second and Third Embodiments). Further, the temperature coefficient G may change according to the elapsed time even within the same operation mode (Fourth Embodiment).

Although the image forming apparatus 100 is used as an example in the above description, the configurations of the first to fourth embodiments can be applied to other apparatuses. That is, the configurations of the first to fourth embodiments are applicable to any apparatus that has a power supply unit supplying power to a load and a cooling mechanism for cooling the power supply unit, and that is capable of operating in multiple operation modes with different power consumption levels.

According to the present disclosure described above, the temperature of the power supply unit can be controlled by appropriately controlling the operation of the cooling fan in accordance with the operation mode.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-078810, filed May 9, 2025, which is hereby incorporated by reference herein in its entirety.

What is claimed is:

1. An image forming apparatus, comprising:
a power supply unit configured to supply power to a load configured to be used in or related to image formation,
a cooling fan configured to cool the power supply unit, and
a processor configured to control driving of the cooling fan,
wherein the image forming apparatus is configured to operate in a plurality of operation modes, and
wherein the processor is configured to control the driving of the cooling fan based on:
an execution period in which the image forming apparatus is operating in a first operation mode among the plurality of operation modes; and
a first setting value among a plurality of setting values each corresponding to a respective one of the plurality of setting values, the first setting value corresponding to the first operation mode.

2. The image forming apparatus according to claim 1, wherein the processor is configured to:
determine, in a case where the first operation mode is to be executed, a predicted value corresponding to a temperature of the power supply unit by calculating the execution period and the first setting value corresponding to the first operation mode; and
control, based on the predicted value, the driving of the cooling fan.

3. The image forming apparatus according to claim 1, wherein the processor is configured to:
determine, in a case where a plurality of operation modes is to be executed, a predicted value corresponding to a temperature of the power supply unit by calculating the execution period and setting values set for respective operation modes to be executed; and
control the driving of the cooling fan based on a sum of the predicted values for each operation mode to be executed.

4. The image forming apparatus according to claim 2, wherein the processor is configured to determine the predicted value by cumulatively adding the first setting value at each predetermined time interval during the execution period.

5. The image forming apparatus according to claim 4,
further comprising a memory configured to store an initial value of the predicted value,
wherein the processor is configured to calculate the predicted value by adding the setting values to the initial value in a case where the execution time has elapsed for the first time after the power supply of the image forming apparatus is turned on.

6. The image forming apparatus according to claim 4,
wherein the setting value is a positive value for an operation mode in which the load is driven, and
wherein the setting value is a negative value for an operation mode in which the load is not driven.

7. The image forming apparatus according to claim 6,
wherein the loads include an image reading unit configured to read an image of a document and an image forming unit configured to form an image on a recording material,
wherein the operation mode in which the load is driven includes at least one of;
a copy mode in which an image read by the image reading unit is formed onto the recording material;
a scan mode in which an image is read by the image reading unit; and
a print mode in which an image is formed onto the recording material by the image forming unit according to a job, and
wherein the operation mode in which the load is not driven includes at least one of:
a standby mode in which an input of a job is awaited; and
a sleep mode in which less power is consumed than in a standby mode.

8. The image forming apparatus according to claim 1,
further comprising a temperature detection unit configured to detect a temperature around the image forming apparatus,
wherein the processor is configured to correct the setting value for each operation mode based on the temperature detected by the temperature detection unit.

9. The image forming apparatus according to claim 1,
further comprising an optional apparatus connected to the image forming apparatus and configured to be supplied with power from the power supply unit when in use,
wherein the processor is configured to correct the setting value for each operation mode using a correction value based on a type of the optional apparatus in a case where the optional apparatus is used.

10. The image forming apparatus according to claim 1, wherein the processor is configured to change the setting value according to an elapsed time of an operation in the operation mode.

11. The image forming apparatus according to claim 1, wherein the cooling fan is a fan configured to cool the power supply unit by ventilating.

12. The image forming apparatus according to claim 1, wherein each of the plurality of setting values is set, with respect to a temperature variation amount in a case where the image forming apparatus operates in a reference operation mode, according to a ratio of a temperature variation amount in a case where the image forming apparatus operates in a corresponding operation mode.

13. An apparatus, comprising:
a power supply unit configured to supply power to a load,
a cooling fan configured to cool the power supply unit, and
a processor configured to control driving of the cooling fan,
wherein the apparatus is configured to operate in a plurality of operation modes,
wherein the processor is configured to control the driving of the cooling fan based on:
an execution period in which the apparatus is operating in one mode among the plurality of operation modes; and
a setting value corresponding to the one operation mode among a plurality of setting values each corresponding to a respective one of the plurality of setting values.
